(19) United States
(12) Patent Application Publication
(10) Pub. No.: US 2012/0037954 A1
(43) Pub. Date: Feb. 16, 2012

(54) Equal Potential Ring Structures of Power Semiconductor with Trenched Contact

(75) Inventor: Fwu-Iuan Hshieh, Santa Clara, CA (US)

(73) Assignee: FORCE MOS TECHNOLOGY CO LTD, Taipei County (TW)

(21) Appl. No.: 12/853,520

(22) Filed: Aug. 10, 2010

(51) Int. Cl. H01L 27/082; H01L 21/768; H01L 27/088

(52) U.S. Cl. 257/139; 257/331; 438/669; 257/E21.575; 257/E27.06; 257/E27.055

(57) ABSTRACT

A semiconductor power device with trenched contact having improved equal potential ring (EPR) structures for device die size shrinkage and yield enhancement are disclosed. The invented semiconductor power device comprising a termination area including an equal potential ring (EPR) formed with EPR contact metal plug penetrating through an insulation layer covering top surface of epitaxial layer and extended downward into an epitaxial layer. To prevent the semiconductor power device from EPR damage induced by die pick-up nozzle at assembly stage in prior art, some preferred embodiments of the present invention without having EPR front metal.

### FIELD OF THE INVENTION

This invention relates generally to a cell structure and device configuration of semiconductor power devices. More particularly, this invention relates to a novel semiconductor power device having equal potential ring structures with trenched contact to further enhanced yield and reliability performance.

### BACKGROUND OF THE INVENTION

In order to ensure the potential around the device edge has same potential after die sawing for uniform breakdown voltage, an equal potential ring (EPR, similarly hereinafter) is formed in termination area of a semiconductor power device surrounding source front metal and gate front metal, as shown in FIG. 1A. The conventional technologies for implementing the EPR structure of prior art is normally connecting EPR front metal to a source-dopant region by a planar contact on top surface of an epitaxial layer in termination area wherein said source-dopant region is formed simultaneously as source region, as shown in FIG. 1B, which is A-B-C-D-E-F cross section of FIG. 1A.

In FIG. 1B, an N-channel trench MOSFET (Metal Oxide Semiconductor Field Effect Transistor) was formed onto an N+ substrate 202 coated with back metal 220 on rear side as drain. Termination area of the trench MOSFET included: an EPR front metal 214 penetrating an insulation layer 201 to planar contact with n+ source-dopant region 215 on top surface of an N epitaxial layer 200 wherein said n+ source-dopant region 215 is formed simultaneously as source region 211; a planar field metal plate 216 overlapping a P body region 204 and a part of the N epitaxial layer 200 in termination area, said planar field metal plate 216 also served as gate front metal and was connected to a wider trenched gate by planar contact on top surface of a poly-silicon layer 210 filled in said wider trenched gate. Meanwhile, the N-channel trench MOSFET comprised active area including: a plurality of trenched gates filled with the poly-silicon layer 210′ padded by a gate oxide layer; P body regions 212 extending between a pair of said trenched gates in the active area; n+ source regions 211 near top surface of said P body regions 212 and surrounding upper portion of said trenched gates in said active area; p+ ohmic contact doped region 213 formed between a pair of said n+ source regions 211 and on top surface of said P body regions 212 to further reduce contact resistance between said P body regions 212 and source front metal 217 by planar contact.

The N-channel MOSFET disclosed in prior art was encountering technical challenges, first of all, in the active area, said n+ source regions 211 and said P body regions 212 were connected to the source front metal 217 by planar contact which requires occupying a large area and was not easily shrunk.

Next, as the device size is getting smaller and smaller with increasing of cell density, the EPR front metal 214 in FIG. 1B is often damaged due to touch with gate front metal induced by die pick-up nozzle at assembly stage. During assembly stage, after die sawing, pick-up nozzle picks up each die by vacuum to lead frame of package, in FIG. 2, the two circles illustrates touching area by the pick-up nozzle. Therefore, the EPR will be easily damaged when the pick-up nozzle touches the EPR front metal, causing EPR shortage with the gate front metal and resulting in low yield and reliability issues as the EPR front metal and the gate front metal have same front metal height.

For other power semiconductor power device, for example N channel trench IGBTs (Insulated Gate Bipolar Transistors) having P+ substrate, the same disadvantage of low yield and reliability issue is also affecting the performance of the power semiconductor device.

Accordingly, it would be desirable to provide a new and improved semiconductor power device configuration to avoid the constraint discussed above.

### SUMMARY OF THE INVENTION

The present invention has been conceived to solve the above-described problems with the related art, and it is an object of the invention to provide a semiconductor power device with trenched contact to make the device easily shrunk, and furthermore, to provide a semiconductor power device in which the EPR structure is formed with contact metal plug and penetrating through an insulation layer and further extends downward into an epitaxial layer without having EPR front metal on the top of the contact metal plug so that the pick-up nozzle will not damage the EPR front metal at assembly stage due to the top surface of the contact metal plug is lower than the gate front metal.

According to a first aspect of the present invention, there is provided a semiconductor power device comprising a termination area including an equal potential ring (EPR) formed with EPR contact metal plug penetrating through an insulation layer covering top surface of an epitaxial layer and connected to an EPR front metal, said semiconductor power device further comprising: a plurality of first type trenched gates in active area and at least a second type trenched gate between the active area and the termination area, filled with a poly-silicon layer and extended into the epitaxial layer from top surface of the epitaxial layer; said EPR contact metal plug filled in an EPR trenched contact penetrating through said insulation layer and further extended downward into the epitaxial layer; a planar field metal plate overlapping a body region and partial of said epitaxial layer in said termination area, said planar field metal plate also serving as gate front metal which is connected to the second type trenched gate for gate connection; said EPR front metal formed over said EPR contact metal plug filled in said EPR trenched contact.

According to a second aspect of the present invention, there is provided a semiconductor power device comprising a termination area including an equal potential ring (EPR) formed with EPR contact metal plug penetrating through an insulation layer covering top surface of an epitaxial layer and without having an EPR front metal, said semiconductor power device further comprising: a plurality of first type trenched gates in active area and at least a second type trenched gate between the active area and the termination area, filled with a poly-silicon layer and extended into the epitaxial layer from top surface of the epitaxial layer; said EPR contact metal plug filled in an EPR trenched contact penetrating through said insulation layer and further extended downward into the epitaxial layer; a planar field metal plate overlapping a body region and partial of said epitaxial layer in said termination area, said planar field metal plate also serving as gate front metal which is connected to the second type trenched gate for gate connection.

Preferred embodiments include one or more of the following features. Said semiconductor power device further comprises a plurality of source-body trenched contacts and at least a gate trenched contact opened through said insulation layer and extended into a source region and a body region of said semiconductor power device and also into the poly-silicon layer filling in the second type trenched gate for gate connection wherein said source-body trenched contact and said gate trenched contact are filled with a source-body contact metal plug and a gate contact metal plug respectively for shrinking the active area of said semiconductor power device. Said semiconductor power device further comprises a source front metal formed onto said insulation layer within said active area and connected to said source region and said body region via said source-body contact metal plug. Said termination area further comprises: a source-dopant region near top surface of said epitaxial layer, said source-dopant region is formed simultaneously as said source region; said EPR contact metal plug penetrating through said insulation layer and further extending through said source-dopant region and into said epitaxial layer. Said termination area further comprises: a body-dopant region within said epitaxial layer, said body-dopant region is formed simultaneously as said body region; said EPR contact metal plug penetrating through said insulation layer and further extending into said body-dopant region. Said EPR trenched contact, said source-body trenched contact and said gate trenched contact all have vertical sidewall. Said EPR trenched contact, said source-body trenched contact and said gate trenched contact all have slope sidewall. Said semiconductor power device further comprises an ohmic contact doped region surrounding at least bottom of said EPR trenched contact and said source-body trenched contact. Said semiconductor power device further comprises an ohmic contact doped region surrounding both bottom and sidewall of said source-body trenched contact adjacent to said body region, and surrounding both bottom and sidewall of said EPR trenched contact underneath said source-dopant region or within said body-dopant region. Said EPR contact metal plug, said source-body contact metal plug and said gate contact metal plug comprise tungsten plugs. Said EPR contact metal plug, said source-body contact metal plug and said gate contact metal plug comprise tungsten plugs padded by a barrier layer of Ti/TiN or Co/TiN or Ta/TiN. Said insulation layer is composed of a BPSG layer of a SRO (Silicon Rich Oxide) layer. Said EPR trenched contact, said source-body trenched contact and said gate trenched contact all have a greater width within said BPSG layer than within other portions.

According to a third aspect of the present invention, there is provided a method of manufacturing a semiconductor power device with EPR formed with EPR contact metal plug without having EPR front metal comprising the steps of: depositing a front metal onto top surface of the semiconductor power device and top surface of said EPR contact metal plug; applying a metal mask onto the front metal; etching the front metal by dry metal etch using Chlorine based gases without etching said EPR contact metal plug.

In the said above, the description has been directed to trench MOSFET. Moreover, this invention is also applicable to a trench IGBT with EPR formed with contact metal plug.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is top view of a trench MOSFET having EPR front metal of prior art.

FIG. 1B is a preferred A-B-C-D-E-F cross-sectional view of FIG. 1.

FIG. 2 is top view of a trench MOSFET illustrating the pick-up nozzle touching area at assembly stage.

FIG. 3 is a preferred embodiment according to the present invention, and also is another preferred A-B-C-D-E-F cross-sectional view of FIG. 1.

FIG. 4 is another preferred embodiment according to the present invention, and also is another preferred A-B-C-D-E-F cross-sectional view of FIG. 1.

FIG. 5 is another preferred embodiment according to the present invention, and also is another preferred A-B-C-D-E-F cross-sectional view of FIG. 1.

FIG. 6 is another preferred embodiment according to the present invention, and also is another preferred A-B-C-D-E-F cross-sectional view of FIG. 1.

FIG. 7 is another preferred embodiment according to the present invention, and also is another preferred A-B-C-D-E-F cross-sectional view of FIG. 1.

FIG. 8 is top view of a trench MOSFET with EPR without EPR front metal according to the present invention.

FIG. 9 is another preferred embodiment according to the present invention, and also is a preferred A₁-B₁-C₁-D₁-E₁-F₁ cross-sectional view of FIG. 8.

FIG. 10 is another preferred embodiment according to the present invention, and also is another preferred A₁-B₁-C₁-D₁-E₁-F₁ cross-sectional view of FIG. 8.

FIG. 11 is another preferred embodiment according to the present invention, and also is another preferred A₁-B₁-C₁-D₁-E₁-F₁ cross-sectional view of FIG. 8.

FIG. 12 is another preferred embodiment according to the present invention, and also is another preferred A₁-B₁-C₁-D₁-E₁-F₁ cross-sectional view of FIG. 8.

FIGS. 13A˜13B are a serial of side cross-sectional views for showing the processing steps for fabricating the trench MOSFET with EPR without EPR front metal.

### DETAILED DESCRIPTION OF THE EMBODIMENTS

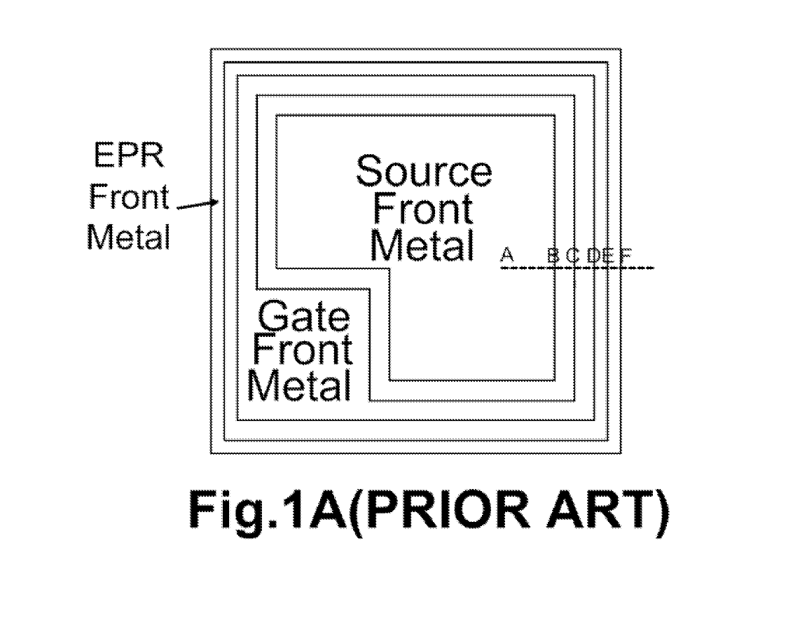

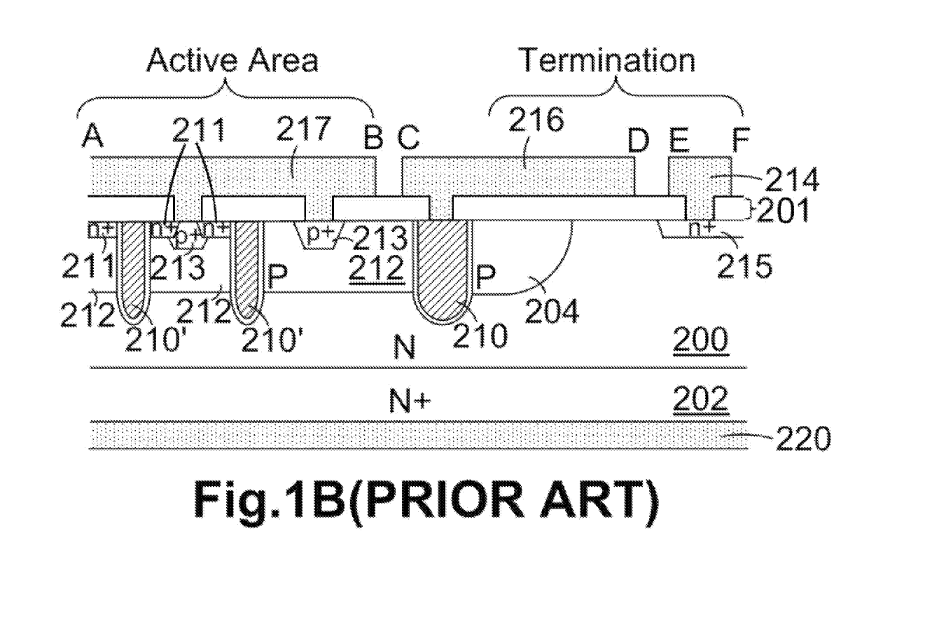

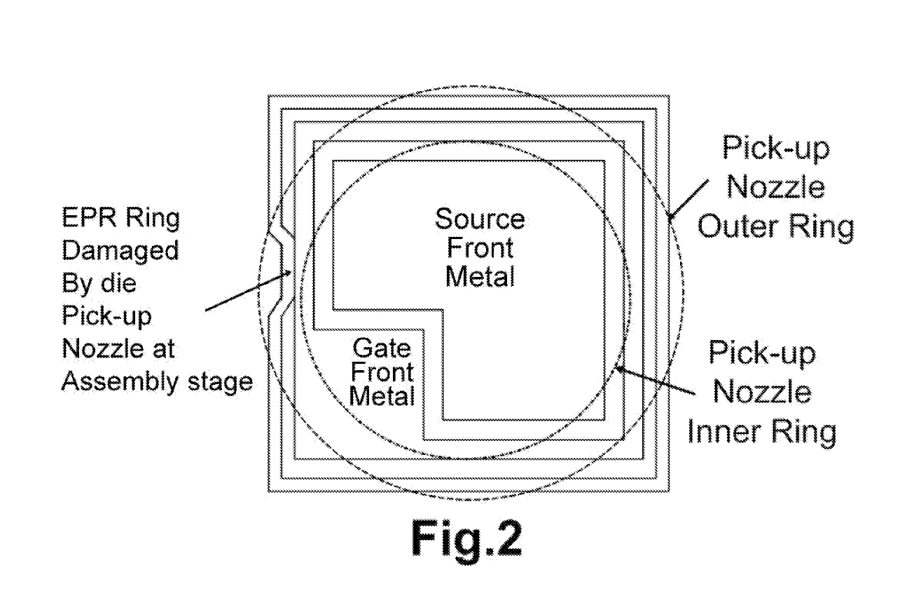

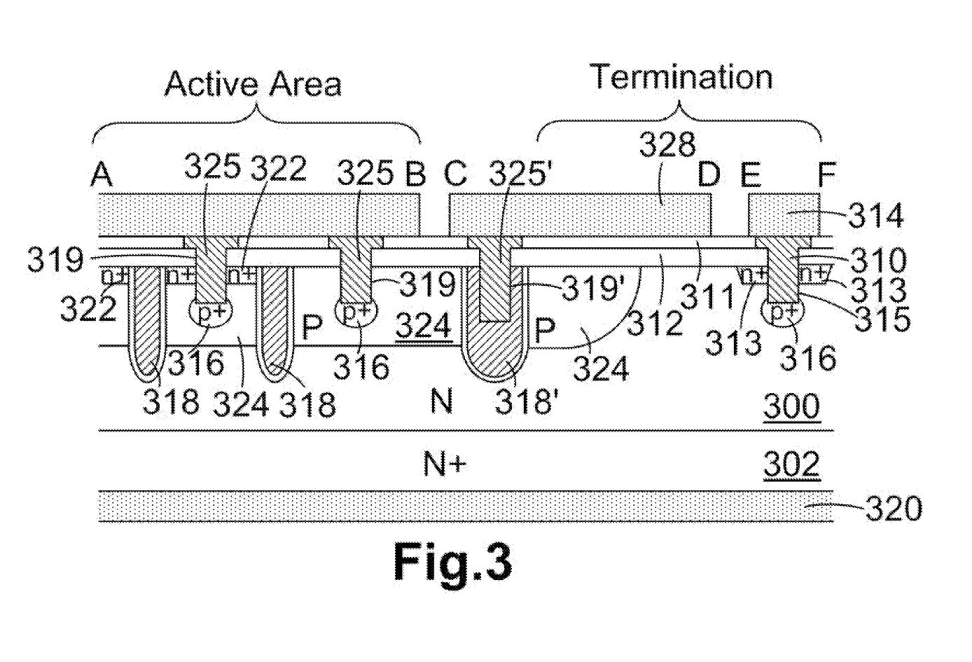

Please refer to FIG. 3 for cross-sectional view of a trench MOSFET according to the present invention which is also another preferred A-B-C-D-E-F cross section of FIG. 1 where an N-channel trench MOSFET is formed onto an N+ substrate 302 coated with back metal 320 as drain. An active area of the N-channel trench MOSFET comprises: a plurality of first type trenched gate filled with a poly-silicon layer 318 padded by a gate oxide layer in active area; at least a second type trenched gate filled with a poly-silicon layer 318′ padded by a gate oxide layer for gate connection between said active area and termination area, said first type trenched gates and said second type trenched gate are extending into an N epitaxial layer 300 from its top surface; a plurality of source-body trenched contacts 319 having vertical sidewall opened through an insulation layer composed of BPSG 311 and SRO (Silicon Rich Oxide) 312 and an n+ source region 322, and extended into a P body region 324. At least a gate trenched contact 319′ hays vertical sidewall opened through said insulation layer and extended into the poly-silicon layer 318′ filling in said second type trenched gate for gate connection. Said source-body trenched contacts and said gate trenched contact are filled with a source-body contact metal plug 325 and a gate contact metal plug 325′, respectively for shrinking the active area of said semiconductor power device; a p+ ohmic contact doped region 316 surrounding at least bottom of each source-body trenched contact, having doping concentration higher than said P body region 324; a source front metal 326 formed within said active area and connected to said source-body contact metal plug 325; a gate front metal also serving as planar field metal plate 328 and connected to said gate contact metal plug 325′. More important, the termination area of the N-channel trench MOSFET comprises: an EPR formed with EPR tungsten plug 310 padded with a barrier layer of Ti/TiN or Co/TiN or Ta/TiN wherein said EPR tungsten plug 310 is penetrating through said insulation layer and an n+ source-dopant region 313 and extended into said N epitaxial layer 300, and said n+ source-dopant region 313 is formed simultaneously as said source region 322; an EPR front metal 314 formed over said EPR tungsten plug and connected to said EPR tungsten plug; an EPR trenched contact 315 filled with said EPR tungsten plug and having vertical sidewall; a p+ ohmic contact region 316 formed within said epitaxial layer 300 and surrounding at least bottom of said EPR trenched contact 315; a P body region 324 within said epitaxial layer 300 next to said second type trenched gate; a planar filed metal plate 328 overlapping said P body region 324 and partial of said epitaxial layer 300 wherein said planar field metal plate 328 also serves as gate front metal. Besides, said EPR trenched contact 315, said source-body trenched contact 319 and said gate trenched contact 319′ all have greater wider within the BPSG layer 311 than within other portions.

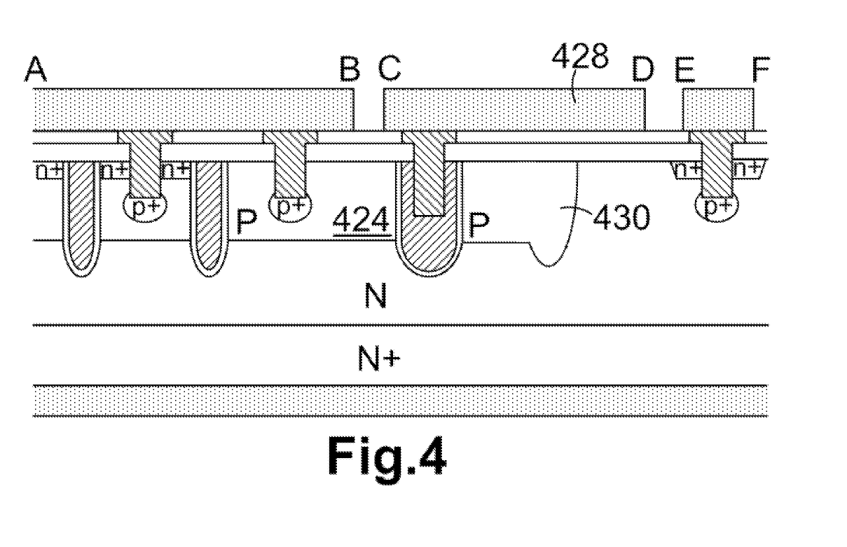

FIG. 4 is another preferred A-B-C-D-E-F cross section of FIG. 1 where the N-channel trench MOSFET is similar to that in FIG. 3 except that, at least a P type guard ring 430 having a deeper junction depth than the P body region 424 is disposed underneath the planar field metal plate 428.

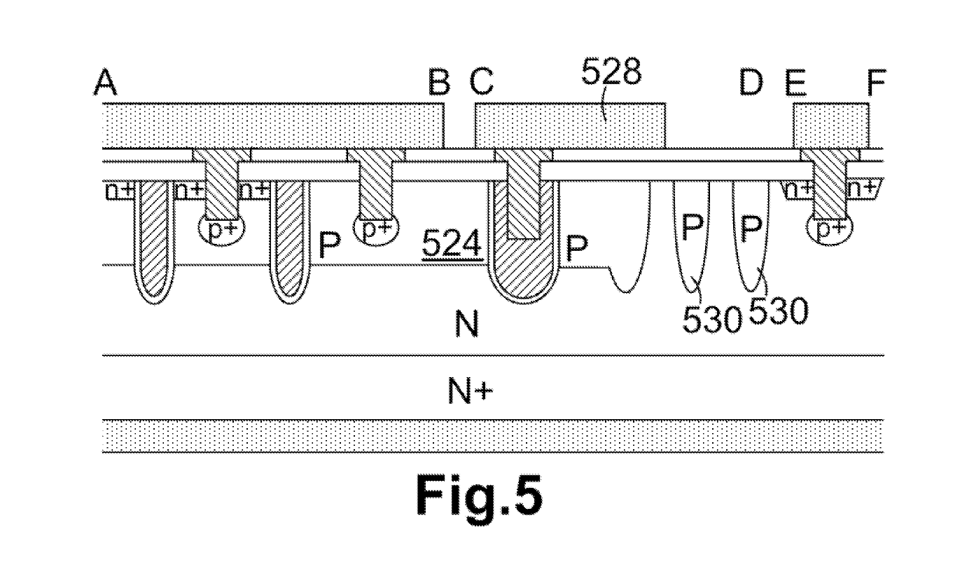

FIG. 5 is another preferred A-B-C-D-E-F cross section of FIG. 1 where the N-channel trench MOSFET is similar to that in FIG. 4 except that, multiple P type floating guard rings 530 having a deeper junction depth than P body region 524 are disposed between the planar filed metal plate 528 and the EPR.

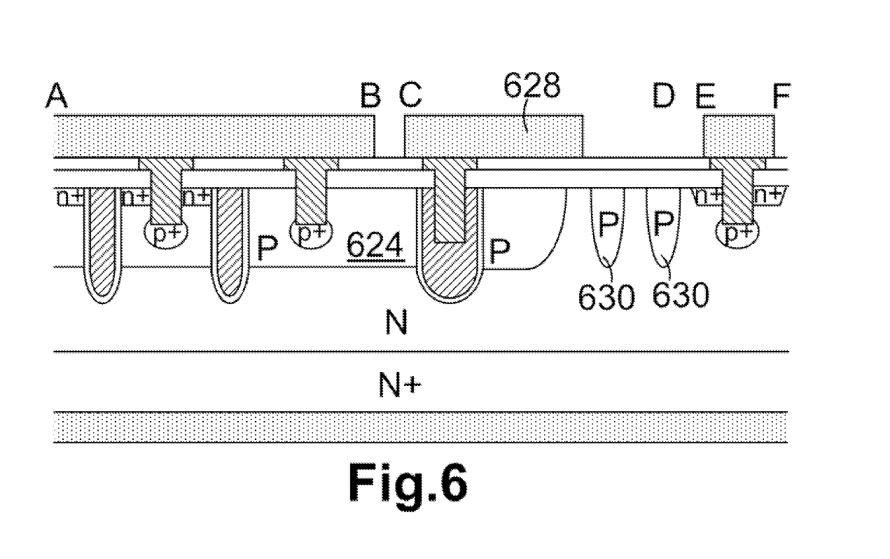

FIG. 6 is another preferred A-B-C-D-E-F cross section of FIG. 1 where the N-channel trench MOSFET is similar to that in FIG. 3 except that, multiple P floating body regions 630 are disposed between the planar filed metal plate 628 and the EPR.

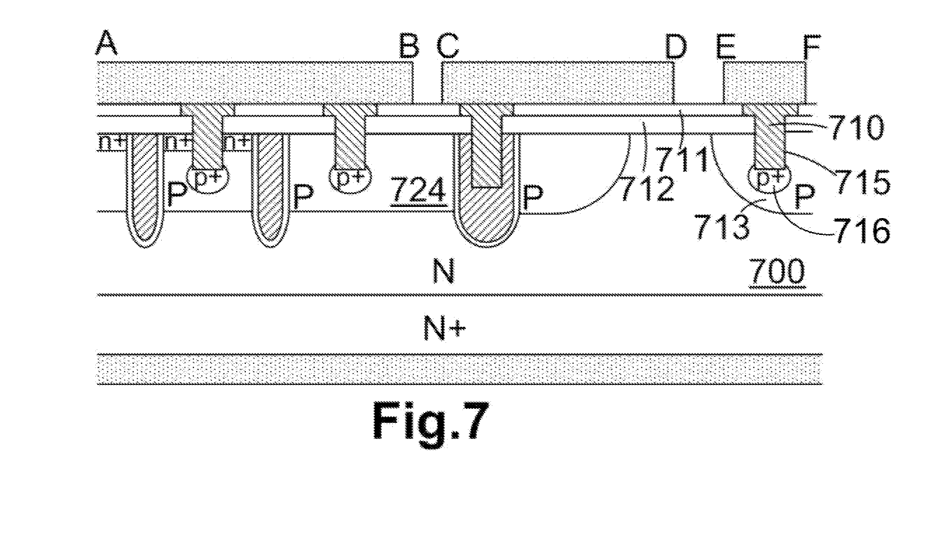

Please refer to FIG. 7 for cross-sectional view of another trench MOSFET according to the present invention which is also another preferred A-B-C-D-E-F cross section of FIG. 1 where the N-channel trench MOSFET is similar to that in FIG. 3 except that, in termination area, the N-channel trench MOSFET in FIG. 7 comprises: a P body-dopant region 713 disposed near the device edge within the epitaxial layer 700 wherein said P body-dopant region 713 is formed simultaneously as the P body region 724; the EPR trenched contact 715 filled with the EPR tungsten plug 710 padded by a barrier layer of Ti/TiN or Co/TiN or Ta/TiN is penetrating through the BPSG layer 711 and the SRO layer 712 and extending into said P-dopant region 713. a p+ ohmic contact region 716 formed within said epitaxial layer 300 and surrounding at least bottom of said EPR trenched contact 715

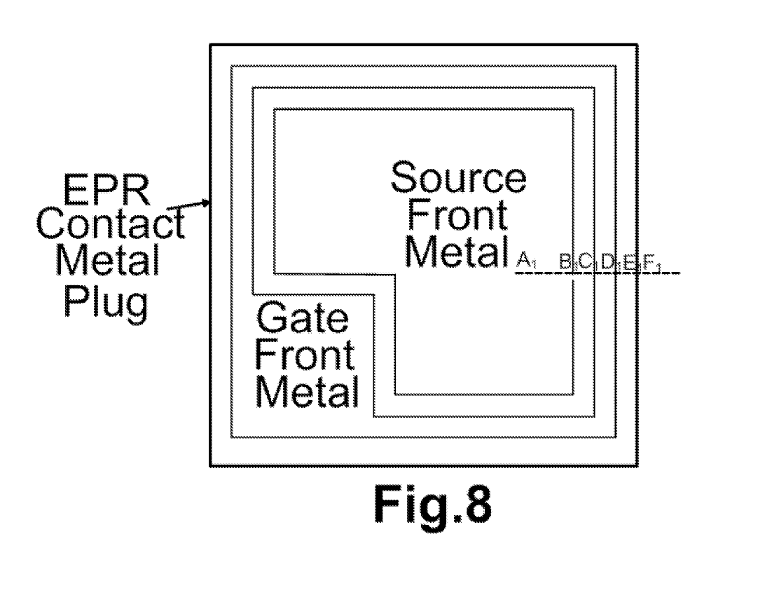

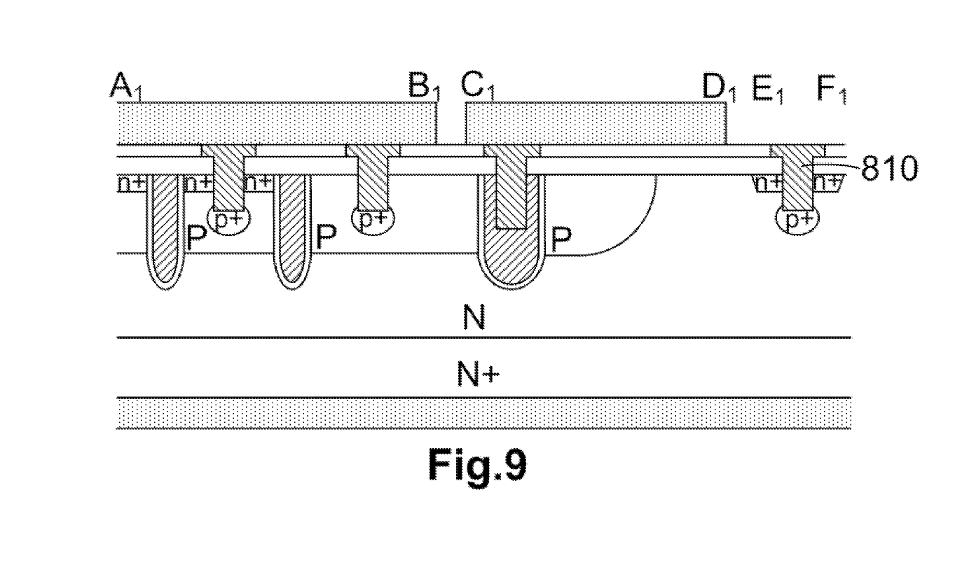

Please refer to FIG. 8 for top view of a semiconductor power device according to the present invention. Compared to FIG. 1, there is no EPR front metal but only EPR contact metal plug surrounding gate front metal. FIG. 9 is a preferred A₁-B₁-C₁-D₁-E₁-F₁ cross section of FIG. 8 where the N-channel trench MOSFET is similar to that in FIG. 3 except that, there is no EPR front metal over the EPR tungsten plug 810.

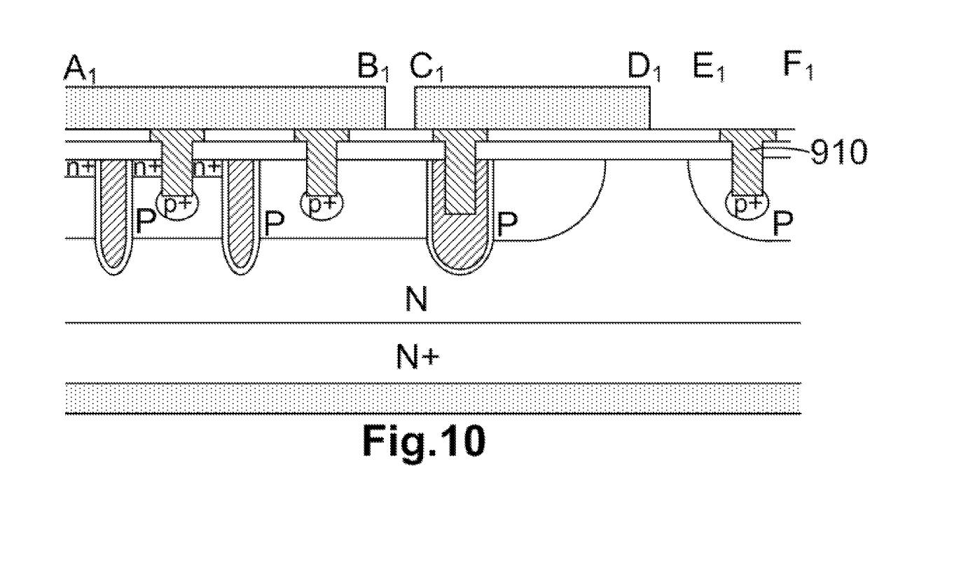

FIG. 10 is another preferred A₁-B₁-C₁-D₁-E₁-F₁ cross section of FIG. 8 where the N-channel trench MOSFET is similar to that in FIG. 7 except that, there is no EPR front metal over EPR tungsten plug 910.

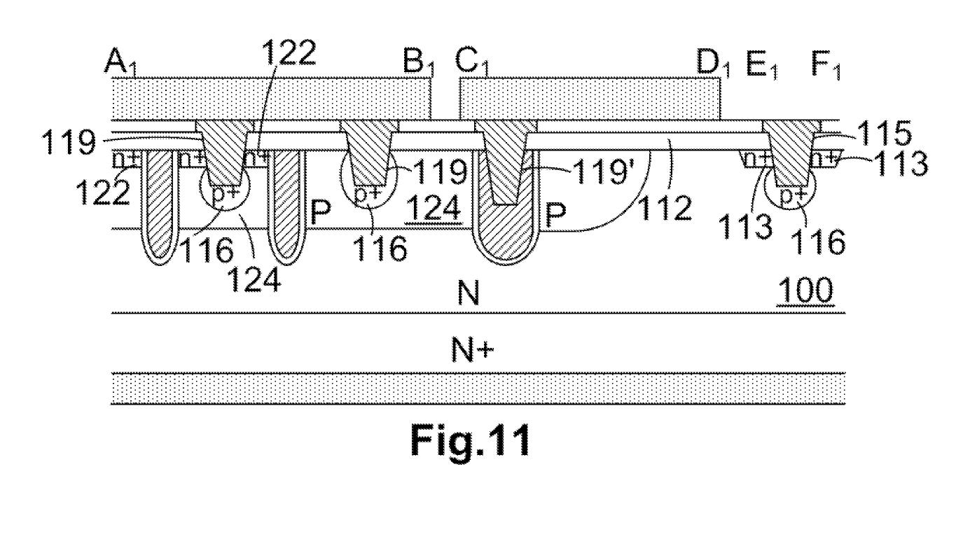

FIG. 11 is another preferred A₁-B₁-C₁-D₁-E₁-F₁ cross section of FIG. 8 where the N-channel trench MOSFET is similar to that in FIG. 9 except that, the EPR trenched contact 115, the source-body trenched contact 119 and the gate trenched contact 119′ all have slope sidewall within the SRO layer 112, the n+ source-dopant region 113, the n+ source region 122, the P body region 124 and the N epitaxial layer 100. Therefore, the p+ ohmic contact doped region 116 is enlarged surrounding both bottom and sidewall of the EPR trenched contact 115 underneath the n+ source-dopant region 113, and surrounding both bottom and sidewall of the source-body trenched contact 119 adjacent to the P body region 124.

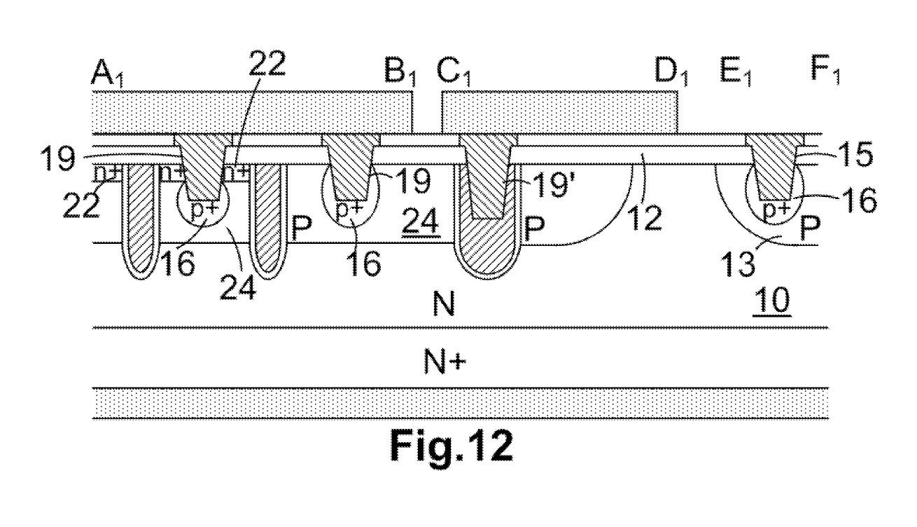

FIG. 12 is another preferred A₁-B₁-C₁-D₁-E₁-F₁ cross section of FIG. 8 where the N-channel trench MOSFET is similar to that in FIG. 10 except that, the EPR trenched contact 15, the source-body trenched contact 19 and the gate trenched contact 19′ all have slope sidewall within the SRO layer 12, the P body-dopant region 13, the n+ source region 22, the P body region 24 and the N epitaxial layer 10. Therefore, the p+ ohmic contact doped region 16 is enlarged surrounding both bottom and sidewall of the EPR trenched contact 15 within the P body-dopant region 13, and surrounding both bottom and sidewall of the source-body trenched contact 19 adjacent to the P body region 24.

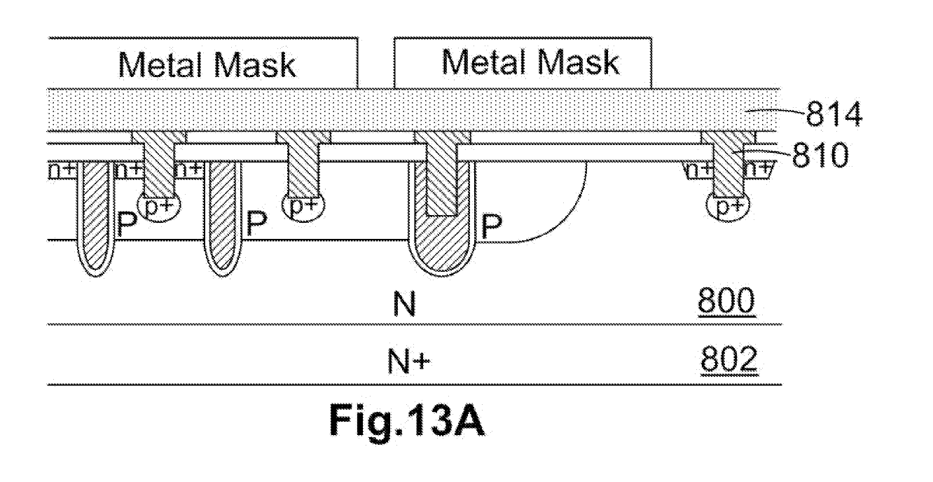

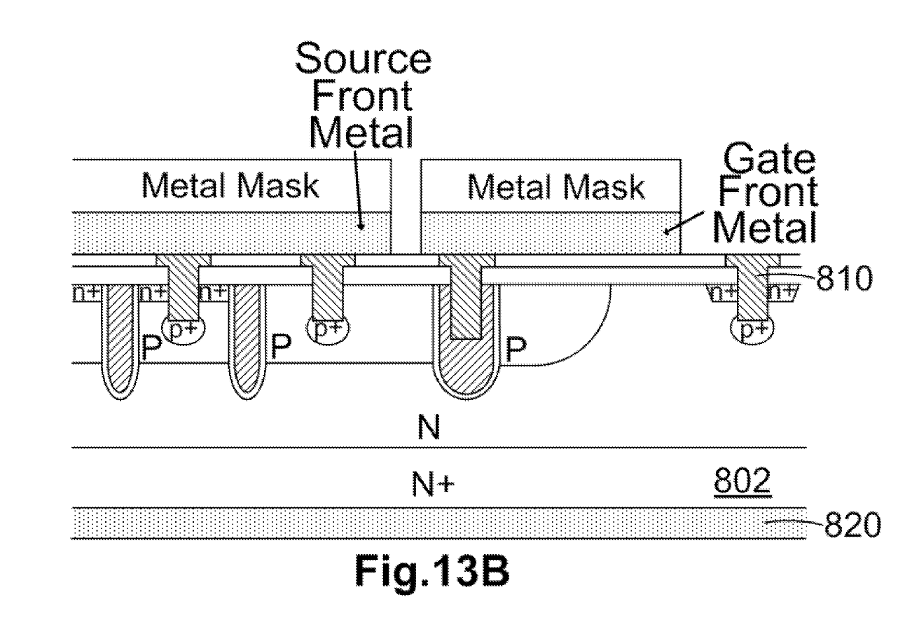

FIG. 13A and FIG. 13B are a serial of exemplary steps that are performed to form the preferred N-channel trench MOSFET with EPR tungsten plug but without having EPR front metal as shown in FIG. 9. In FIG. 13A, an N-channel trench MOSFET with trenched contact and EPR tungsten plug 810 has already formed in an N epitaxial layer 800 onto an N+ substrate 802 Then, a front metal 814, for example Ti/Al alloys or Ti/TiN/Al alloys, is deposited onto top surface of the N-channel trench MOSFET and EPR tungsten plug 810, and a metal mask is applied to pattern said front metal 814.

In FIG. 13B, a step of dry metal etch, for example dry Al etch, is carried out using Chlorine based gases such as mixture of BCl₃ and Cl₂ which will not etch EPR tungsten plug 810 for prevention. After that, the front metal is patterned into source front metal and gate front metal, respectively. Then, a back metal 820, for example Ti/Ni/Ag is deposited on rear side of the N+ substrate 802 as drain metal after grinding.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A semiconductor power device comprising a termination area including an equal potential ring (EPR) formed with an EPR contact metal plug near edge of said semiconductor power device, said semiconductor power device further comprising:
a plurality of first type trenched gates in an active area and at least a second type trench gates between said active area and said termination area;
said first type trenched gates and said second type trenched gate filled with a poly-silicon layer padded by a gate oxide layer and extended into an epitaxial layer of a first conductivity type;
said EPR contact metal plug filled in an EPR trenched contact penetrates through an insulation layer and further extended downward into said epitaxial layer;
at least a gate trenched contact filled with a gate contact metal plug and opened through said insulation layer extended into said poly-silicon layer filling in said second type trenched gate;
a planar field metal plate on top of said insulation layer overlapping a body region of a second conductivity type and partial of said epitaxial layer in said termination area; and
said planar field metal plate also serves as a gate front metal connected to said second type trenched gate via said gate contact metal plug.

2. The semiconductor power device of claim 1, further comprising an EPR front metal covering top surface of said EPR contact metal plug.

3. The semiconductor power device of claim 1, wherein there is no an EPR front metal covering top surface of said EPR contact metal plug.

4. The semiconductor power device of claim 1, further comprising:
at least a guard ring region of said second conductivity type overlapped with said planar field metal plate, wherein said guard ring region has a deeper junction depth than said body region.

5. The semiconductor power device of claim 1, further comprising:
multiple floating guard ring regions or multiple floating body regions of said second conductivity type disposed between said planar field metal plate and said EPR.

6. The semiconductor power device of claim 1, wherein said semiconductor power device is trench MOSFET, and said epitaxial layer is grown on a substrate of said first conductivity type.

7. The semiconductor power device of claim 1, wherein said semiconductor power device is trench IGBT, and said epitaxial layer is grown on a substrate of said second conductivity type.

8. The semiconductor power device of claim 1, wherein said active area further comprises:
a plurality of source-body trenched contacts opened through said insulation layer and a source region of said first conductivity type and extended into said body region between two adjacent said first type trenched gates, filled with a source-body contact metal plug;
an ohmic contact doped region of said second conductivity type surrounding at least bottom of each said source-body contact metal plug in said body region;
said ohmic contact doped region having a higher doping concentration than said body region; and
a source front metal formed onto said insulation layer within said active area and connected to said source region and said body region via said source-body contact metal plug.

9. The semiconductor power device of claim 8, wherein said termination area further comprises:
a source-dopant region of said first conductivity type formed near edge of said semiconductor power device, wherein said source-dopant region is formed simultaneously as said source regions in said active area;
said EPR contact metal plug penetrating through said insulation layer and said source-dopant region, and further extended into said epitaxial layer;
an ohmic contact doped region of said second conductivity type surrounding at least bottom of said EPR contact metal plug underneath said source-dopant region; and
said ohmic contact doped region having a higher doping concentration than said body region.

10. The semiconductor power device of claim 1, wherein said termination area further comprises:
a body-dopant region disposed near edge of said semiconductor power device, wherein said body-dopant region is formed simultaneously as said body regions;
said EPR contact metal plug penetrating through said insulation layer and further extending into said body-dopant region;
an ohmic contact doped region of said second conductivity type surrounding at least bottom of said EPR contact metal plug; and
said ohmic contact doped region having a higher doping concentration than said body-dopant region.

11. The semiconductor power device of claim 1, wherein said EPR trenched contact and said gate trenched contact have vertical sidewall.

12. The semiconductor power device of claim 8, wherein said source-body trenched contact has vertical sidewall.

13. The semiconductor power device of claim 1, wherein said EPR trenched contact and said gate trenched contact have slope sidewall.

14. The semiconductor power device of claim 8, wherein said source-body trenched contact has slope sidewall.

15. The semiconductor power device of claim 1, wherein said EPR contact metal plug and said gate contact metal plug comprise a tungsten plug padded with Ti/TiN, Ta/TiN or Co/TiN.

16. The semiconductor power device of claims 8, wherein said source-body contact metal plug comprises a tungsten plug padded with Ti/TiN, Ta/TiN or Co/TiN.

17. The semiconductor power device of claim 1, wherein said planar field metal plate and said gate front metal are Ti/Al alloys or Ti/TiN alloys.

18. The semiconductor power device of claim 2, wherein said EPR front metal comprises Ti/Al alloys or Ti/TiN alloys.

19. The semiconductor power device of claim 8, wherein said source front metal comprises Ti/Al alloys or Ti/TiN alloys.

20. The semiconductor power device of claim 1, wherein said insulation layer comprises a BPSG layer and a SRO layer.

21. The semiconductor power device of claim 15, wherein said EPR trenched contact, said source-body trenched contact and said gate trenched contact have a greater contact width within said BPSG layer than within other portions.

22. A method for manufacturing a semiconductor power device of claim 3, comprising the steps of:
depositing a front metal onto top surface of said semiconductor power device and top surface of said contact metal plug;
applying a metal mask onto said front metal wherein said metal mask is open in the area of said EPR; and
etching said front metal by dry metal etch using Chlorine based gases which will etch said front metal on top of said EPR without etching said contact metal plug of said EPR.

23. The method of claim 22, wherein said front metal comprises Ti/Al alloys or Ti/TiN alloys.

24. The method of claim 22, wherein said Chlorine based gases comprise a mixture of BCl₃ and Cl₂.

25. The method of claim 22, wherein said metal plug comprises a tungsten plug padded by a barrier layer of Ti/TiN or Co/TiN or Ta/TiN.
